(19) United States
(12) Patent Application Publication
(10) Pub. No.: US 2026/0018385 A1
(43) Pub. Date: Jan. 15, 2026

(54) GAS DISTRIBUTION MODULE, SUBSTRATE PROCESSING METHOD, AND SUBSTRATE PROCESSING APPARATUS

(71) Applicant: SEMES CO., LTD., Cheonan-si (KR)

(72) Inventors: Seong Gil LEE, Cheonan-si (KR); Wan Jae PARK, Cheonan-si (KR); Joun Taek KOO, Cheonan-si (KR); Woo Chool JANG, Cheonan-si (KR); Young Seo PARK, Cheonan-si (KR); Seong Hak BAE, Cheonan-si (KR); Dong Sub OH, Cheonan-si (KR)

(73) Assignee: SEMES CO., LTD., Cheonan-si (KR)

(21) Appl. No.: 19/186,993

(22) Filed: Apr. 23, 2025

(30) Foreign Application Priority Data
Jul. 15, 2024 (KR) 10-2024-0093309

(51) Int. Cl. H01J 37/32; H01L 21/67

(52) U.S. Cl. CPC H01J 37/32449; H01J 37/32422; H01J 37/32541; H01L 21/67017; H01J 2237/24585; H01J 2237/334

(57) ABSTRACT

Disclosed are a gas distribution module capable of effectively adjusting the recombination rate of radical components, a substrate processing method, and a substrate processing apparatus. The gas distribution module configured to supply a gas to a processing region in a substrate processing apparatus using plasma includes an upper electrode, an ion blocker disposed under the upper electrode to form a plasma generation region, a showerhead disposed under the ion blocker to form a recombination region, and a purge gas supply unit configured to supply a purge gas to the recombination region.

### CROSS-REFERENCE TO THE RELATED APPLICATION

The present application claims priority to and the benefit of Korean Patent Application No. 10-2024-0093309, filed on Jul. 15, 2024, in the Korean Intellectual Property Office, the entire disclosure of which is incorporated herein by reference.

### BACKGROUND

### 1. Field

The present disclosure relates to a gas distribution module configured to supply a gas to a processing region on a substrate, a substrate processing method performed by the gas distribution module, and a substrate processing apparatus including the gas distribution module.

### 2. Description of the Related Art

A semiconductor (or display) manufacturing process is a process for manufacturing a semiconductor device on a substrate (e.g., a wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A method of processing a substrate using plasma formed inside a process chamber and a method of processing a substrate using remote plasma generated outside a process chamber are being used.

Meanwhile, a device for selectively etching silicon germanium (SiGe) on a substrate is disclosed in Korean Patent Laid-Open Publication No. 10-2023-0029463. Fluorine gas (F₂) is used for selective etching of silicon germanium (SiGe). Fluorine gas (F₂) is generated by combination of two fluorine radicals (F*). Silicon (Si) may be damaged due to free fluorine remaining after generation of fluorine gas (F₂). Therefore, in order to achieve more precise process control, a method of adjusting the recombination rate of fluorine radicals (F*) is required.

### SUMMARY

The present disclosure provides a gas distribution module capable of effectively adjusting the recombination rate of radical components, a substrate processing method, and a substrate processing apparatus.

A gas distribution module configured to supply a gas to a processing region in a substrate processing apparatus using plasma according to the present disclosure includes an upper electrode, an ion blocker disposed under the upper electrode to form a plasma generation region, a showerhead disposed under the ion blocker to form a recombination region, and a purge gas supply unit configured to supply a purge gas to the recombination region.

In the embodiment of the present disclosure, the gas distribution module may further include a support ring located on the upper side of the peripheral portion of the showerhead to support the lower side of the peripheral portion of the ion blocker.

In the embodiment of the present disclosure, the purge gas supply unit may include a purge gas supply source configured to store the purge gas, a purge gas supply line connected between the purge gas supply source and the recombination region through the support ring, and a flow rate control valve configured to control the flow rate of the purge gas supplied through the purge gas supply line.

In the embodiment of the present disclosure, fluorine radicals may be generated in the plasma generation region, and the fluorine radicals may flow to the recombination region through a through-hole formed in the upper electrode and may be combined with one another in the recombination region to generate fluorine gas.

In the embodiment of the present disclosure, the purge gas supply unit may supply a purge gas containing at least one of argon (Ar), nitrogen (N₂), helium (He), or hydrogen (H₂) to the recombination region to adjust the recombination rate of the fluorine radicals.

In the embodiment of the present disclosure, the gas distribution module may further include a pressure gauge configured to measure pressure in the recombination region, and the purge gas supply unit may control the flow rate of the purge gas according to the pressure measured by the pressure gauge.

In the embodiment of the present disclosure, the gas distribution module may include a gas distribution plate. A gas supply region may be formed in a space between the gas distribution plate and the upper electrode. The gas distribution plate may include a first through-hole formed therein so as to communicate with a gas supply unit configured to supply a process gas for generation of plasma.

In the embodiment of the present disclosure, the upper electrode may be electrically connected to a power supply unit configured to supply radio-frequency (RF) power for generation of plasma, and may include a second through-hole formed therein so as to allow a process gas to flow from the gas supply region to the plasma generation region therethrough.

In the embodiment of the present disclosure, the ion blocker may include a third through-hole formed therein so as to allow radical components of plasma generated in the plasma generation region to pass therethrough.

In the embodiment of the present disclosure, the showerhead may include a fourth through-hole formed therein so as to allow fluorine gas generated by recombination of fluorine radicals in the recombination region to pass therethrough.

A substrate processing method performed by the above-described gas distribution module configured to supply a processing gas to a processing region on a substrate in a substrate processing apparatus using plasma according to the present disclosure includes supplying a process gas to the plasma generation region, applying RF power to the plasma generation region to generate plasma, supplying the purge gas to the recombination region to adjust the recombination rate of radical components in the plasma, and supplying the processing gas generated by recombination of the radical components in the recombination region to the processing region.

In the embodiment of the present disclosure, adjusting the recombination rate of the radical components may include measuring the pressure of a gas in the recombination region and controlling the flow rate of the purge gas according to the pressure.

In the embodiment of the present disclosure, the process gas may include at least one of fluorine (F), nitrogen (N₂), argon (Ar), or helium (He).

A substrate processing apparatus using plasma according to the present disclosure includes a process chamber configured to form a processing region on a substrate, a substrate support unit disposed in the process chamber to support the substrate, a gas supply unit configured to supply a process gas for generation of plasma, a power supply unit configured to supply radio-frequency (RF) power for generation of plasma, and a gas distribution module configured to receive the process gas supplied from the gas supply unit, to generate the plasma using the RF power supplied from the power supply unit, and to distribute a processing gas from the plasma to the processing region.

### BRIEF DESCRIPTION OF THE DRAWINGS

The accompanying drawings, which are incorporated in this specification, illustrate exemplary embodiments and serve to further illustrate the technical ideas of the disclosure in conjunction with the detailed description of exemplary embodiments that follows, and the disclosure is not to be construed as limited to what is shown in such drawings. In the drawings:

FIG. 1 is a view schematically showing the structure of a substrate processing apparatus according to the present disclosure;

FIG. 2 is an enlarged view of portion A in FIG. 1;

FIG. 3 is a view showing the structure of a gas distribution module in the substrate processing apparatus according to the present disclosure; and

FIG. 4 is a flowchart showing a method of processing a substrate by the gas distribution module according to the present disclosure.

### DETAILED DESCRIPTION OF EXEMPLARY EMBODIMENTS

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

A substrate processing apparatus as semiconductor manufacturing equipment of the embodiment may be used to perform a process on a substrate such as a semiconductor wafer or a flat display panel. In particular, the substrate processing apparatus 100 of the embodiment is an apparatus that performs an etching or deposition process on a substrate using plasma.

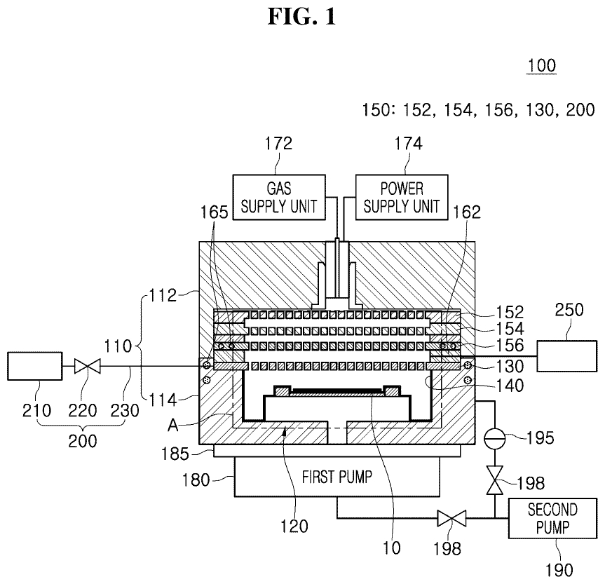

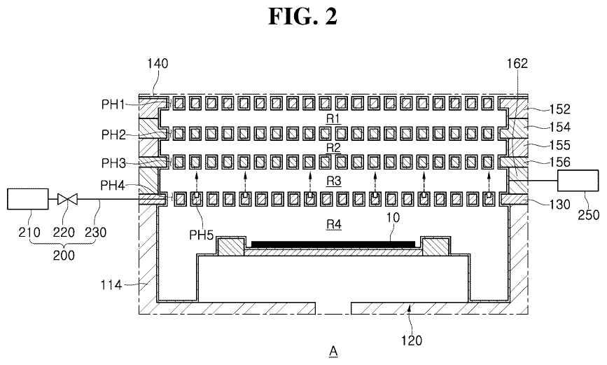

FIG. 1 is a view schematically showing the structure of the substrate processing apparatus 100 according to the present disclosure. FIG. 2 is an enlarged view of portion A in FIG. 1. The substrate processing apparatus 100 using plasma according to the present disclosure includes a process chamber 110 configured to form a processing region R4 on a substrate 10, a substrate support unit 120 disposed in the process chamber 110 to support the substrate 10, a gas supply unit 172 configured to supply a process gas for generation of plasma, a power supply unit 174 configured to supply radio-frequency (RF) power for generation of plasma, and a gas distribution module 150 configured to receive the process gas supplied from the gas supply unit 172, to generate plasma using the RF power supplied from the power supply unit 174, and to distribute a processing gas from the plasma to the processing region R4.

In addition, the substrate processing apparatus 100 may further include a first pump 180, a second pump 190, a first pressure regulator 185, a second pressure regulator 195, and a valve 198.

The substrate processing apparatus 100 may be a dry etching apparatus that performs an etching process on the substrate 10 placed on the substrate support unit 120 using plasma. In some embodiments, the substrate processing apparatus 100 may be a dry cleaning apparatus that performs etch cleaning. In the embodiment, the substrate processing apparatus 100 will be described by way of example as employing a capacitively coupled plasma (CCP) method. However, the plasma forming method of the substrate processing apparatus 100 is not limited thereto. The substrate 10 may be, for example, a silicon wafer used in manufacture of a semiconductor device such as a semiconductor integrated circuit.

The process chamber 110 may provide a space in which plasma is formed and a space in which an etching process is performed. The process chamber 110 may provide a sealed inner space in which the substrate 10 is processed. The process chamber 110 may include an upper chamber 112 surrounding the space in which plasma is formed and a lower chamber 114 surrounding the space in which the etching process is performed. A passage through which the substrate 10 is loaded and unloaded may be formed in one side of the process chamber 110. Alternatively, the substrate 10 may be loaded and unloaded while the lower chamber 114 is separated from the upper chamber 112. The process chamber 110 may be made of metal. For example, the process chamber 110 may include aluminum (Al) or an alloy containing aluminum (Al).

The substrate support unit 120 may be located in a lower portion of the process chamber 110, and may support the substrate 10 while the substrate 10 is processed. The substrate support unit 120 may include, for example, an electrostatic chuck, a heater, and a susceptor. For example, the substrate support unit 120 may be configured such that an electrostatic chuck electrostatically attracts and supports the substrate 10. The substrate support unit 120 may heat or cool the substrate 10 to adjust the temperature of the substrate 10. According to the embodiment, the substrate support unit 120 may be raised and lowered. Alternatively, support pins included in the substrate support unit 120 may be raised and lowered to adjust the height of the substrate 10.

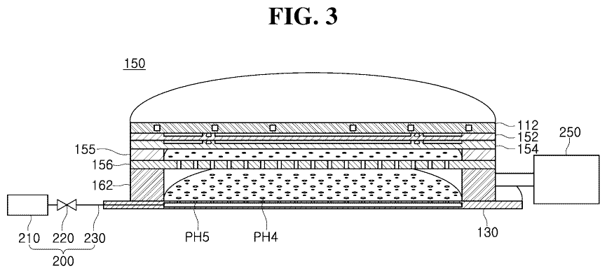

The gas supply unit 172 may supply a process gas required for generation of plasma, and the process gas may be supplied to a plasma generation region R2 through a gas supply region R1. In the substrate processing apparatus 100, the gas distribution module 150 may have the structure shown in FIG. 3. The gas supply region R1 includes at least a portion of the region between the gas supply unit 172 and an upper electrode 154. The power supply unit 174 may supply RF power required for generation of plasma. For example, the power supply unit 174 may apply, to the upper electrode 154, RF power in the form of electromagnetic waves having a predetermined frequency and intensity. An ion blocker 156 may be connected to a ground. Accordingly, the plasma generation region R2 may be formed between the upper electrode 154 and the ion blocker 156.

Referring to FIG. 3, a showerhead 130 is located at the bottom of the gas distribution module 150. A support ring 162 is disposed on the upper side of the peripheral portion of the showerhead 130. The ion blocker 156 is located on the top of the support ring 162. A recombination region R3 is formed by the showerhead 130, the support ring 162, and the ion blocker 156. A purge gas supply unit 200 is connected so that a purge gas is supplied to the recombination region R3 through the support ring 162.

A dielectric ring 155 is disposed on the upper side of the peripheral portion of the ion blocker 156. The upper electrode 154 is disposed on the top of the dielectric ring 155. The plasma generation region R2 is formed by the ion blocker 156, the dielectric ring 155, and the upper electrode 154.

A gas distribution plate 152 is disposed on the upper electrode 154. The upper electrode 154 may have a shape in which the upper side of the peripheral portion thereof protrudes upward. That is, the peripheral portion of the gas distribution plate 152 may be supported by the protruding peripheral portion of the upper electrode 154. The gas supply region R1 may be formed in the space between the gas distribution plate 152 and the upper electrode 154. The upper side of the gas distribution plate 152 may be covered by the upper chamber 112. A through-hole may be formed in the central portion of the upper chamber 112 so as to be connected to the gas supply unit 172 and the power supply unit 174.

The gas distribution module 150 may supply the process gas supplied from the gas supply unit 172 to the processing region R4 on the substrate 10. The gas distribution module 150 includes a gas distribution plate 152, an upper electrode 154 disposed under the gas distribution plate 152 to form the gas supply region R1, an ion blocker 156 disposed under the upper electrode 154 to form the plasma generation region R2, a showerhead 130 disposed under the ion blocker 156 to form the recombination region R3, and a purge gas supply unit 200 configured to supply a purge gas to the recombination region R3.

The upper electrode 154 and the ion blocker 156 are electrode plates to which power for generation of plasma is applied, as described above. In order to allow gas or plasma to pass therethrough, the gas distribution plate 152 may include one or more first through-holes PH1 formed therein, the upper electrode 154 may include one or more second through-holes PH2 formed therein, the ion blocker 156 may include one or more third through-holes PH3 formed therein, and the showerhead 130 may include one or more fourth through-holes PH4 formed therein. Referring to FIG. 2, the first through-holes PH1, which communicate with the gas supply unit 172 that supplies a process gas for generation of plasma, may be formed in the gas distribution plate 152. The upper electrode 154 may be electrically connected to the power supply unit 174 that supplies RF power for generation of plasma, and the second through-holes PH2, through which a process gas flows from the gas supply region R1 to the plasma generation region R2, may be formed in the upper electrode 154. The third through-holes PH3, through which radical components of the plasma generated in the plasma generation region R2 pass, may be formed in the ion blocker 156. The fourth through-holes PH4, through which fluorine gas (F₂) generated by recombination of fluorine radicals in the recombination region R3 passes, may be formed in the showerhead 130. Meanwhile, purge gas supply holes PH5, through which a purge gas supplied from the purge gas supply unit 200 is supplied to the recombination region R3, may be formed in the upper portion of the showerhead 130. Referring to FIGS. 2 and 3, a purge gas flow space capable of receiving a purge gas is defined in the showerhead 130, and the purge gas supply holes PH5 are formed in the showerhead 130 so as to be open upward in the purge gas flow space. The purge gas supplied through the purge gas supply unit 200 may be supplied to the recombination region R3 through the purge gas supply holes PH5. Meanwhile, unlike the purge gas supply holes PH5, the fourth through-holes PH4 penetrate two opposite surfaces (upper and lower surfaces) of the showerhead 130 in order to interconnect the recombination region R3 and the processing region R4.

The gas distribution plate 152, the upper electrode 154, the ion blocker 156, and the showerhead 130 may include metal, for example, aluminum (Al), which is easy to process. In exemplary embodiments, the number of plates included in the gas distribution module 150 may vary. For example, the gas distribution plate 152 may be omitted. Similarly, the gas supply region R1 may be omitted.

The gas distribution module 150 may further include a dielectric ring 155, which is located on the upper side of the peripheral portion of the ion blocker 156 and supports the lower side of the peripheral portion of the upper electrode 154. The dielectric ring 155 may be disposed between the upper electrode 154 and the ion blocker 156 to electrically insulate the upper electrode 154 and the ion blocker 156 from each other. For example, the dielectric ring 155 may include an insulative material, for example, ceramic.

The gas distribution module 150 may further include a support ring 162, which is located on the upper side of the peripheral portion of the showerhead 130 and supports the lower side of the peripheral portion of the ion blocker 156. The support ring 162 may be disposed between the showerhead 130 and the ion blocker 156. The support ring 162 may be made of a dielectric or insulative material.

In order to form a channel in a logic or memory semiconductor, a process of selectively etching silicon germanium (SiGe) in a stacked structure of silicon germanium (SiGe) and silicon (Si) is performed. In order to etch silicon germanium (SiGe), a fluorine etchant is required. Therefore, the gas supply unit 172 supplies a process gas containing fluorine (F) to the plasma generation region R2, and plasma containing fluorine radicals (F*) is generated from the process gas in the plasma generation region R2. The fluorine radical (F*) components in the plasma flow to the recombination region R3, and fluorine gas (F₂) is generated by recombination of the fluorine radicals (F*) in the recombination region R3, and is then supplied to the processing region R4 through the showerhead 130. Thereafter, silicon germanium (SiGe) on the substrate 10 may be selectively etched by the fluorine gas (F₂).

Silicon (Si) of the substrate 10 may be damaged by free fluorine particles remaining after generation of fluorine gas (F₂) in the recombination region R3. In the present disclosure, the recombination rate of fluorine radicals (F*) may be adjusted by the purge gas supply unit 200 supplying a purge gas to the recombination region R3. This is because, as pressure in the recombination region R3 increases, scattering of fluorine radicals (F*) increases, leading to increase in the concentration of fluorine gas (F₂). Since the recombination rate of fluorine radicals (F*) is adjusted by the purge gas supply unit 200, it may be possible to prevent damage to silicon caused by free fluorine particles and to increase the etch rate for silicon germanium (SiGe).

The gas distribution module 150 may include a heater unit 165 to adjust the temperature of the showerhead 130. The heater unit 165 may be provided around the showerhead 130 in order to maintain constant surface temperature of the showerhead 130. For example, the heater unit 165 may be disposed along the periphery of the showerhead 130 or the ion blocker 156 or may be disposed inside a portion of the lower chamber 114 that is adjacent to the showerhead 130. The surface temperature of the showerhead 130 may be adjusted by the heater unit 165 in a range of, for example, about 50° C. to about 200° C. However, the placement position and form of the heater unit 165 may be varied depending on embodiments.

The first pump 180 and the second pump 190 may be connected to the lower chamber 114. The first pump 180 and the second pump 190 may be connected to the interior of the process chamber 110 through, for example, the cavity in the lower chamber 114. The first pump 180 and the second pump 190 may discharge a gas containing a residual gas in the process chamber 110 through the cavity in the lower chamber 114, thereby controlling pressure. The first pump 180 and the second pump 190 may include a vacuum pump. For example, the first pump 180 and the second pump 190 may include a dry pump, a rotary pump, a diffusion pump, a turbomolecular pump, or an ion pump. For example, the first pump 180 may include a turbomolecular pump, and the second pump 190 may include a dry pump. In this case, the first pump 180 may have a higher exhaust speed and a lower pressure range for operation than the second pump 190.

The first pressure regulator 185 and the second pressure regulator 195 may be connected to the first pump 180 and the second pump 190 in order to regulate pressure in the process chamber 110 generated by the first pump 180 and the second pump 190. The first pressure regulator 185 and the second pressure regulator 195 may include, for example, an automatic pressure controller (APC). The valve 198 may be disposed between the first pump 180 and the second pump 190 and between the second pump 190 and the second pressure regulator 195 in order to regulate the flow of gas. However, in exemplary embodiments, the types, numbers, and placement forms of the first pump 180, the second pump 190, the first pressure regulator 185, the second pressure regulator 195, and the valve 198 constituting the exhaust assembly may be varied.

A coating layer 140 may cover at least a portion of each of the inner surface of the process chamber 110, the surface of the substrate support unit 120 exposed through the substrate processing region R4, the surface of the showerhead 130, the surface of the gas distribution plate 152, the surface of the upper electrode 154, and the surface of the ion blocker 156. The coating layer 140 may serve to increase the adsorption rate of radicals, for example, fluorine radicals (F*), thereby securing an appropriate amount of etchant generated in the recombination region R3. The coating layer 140 may have a thickness of about 5 μm to about 30 μm.

The coating layer 140 may include, for example, an electroless plated metal layer or a non-metal layer such as quartz. The coating layer 140 may include at least one of nickel (Ni), copper (Cu), or stainless steel (or Steel Use Stainless (SUS)). The coating layer 140 may further include phosphorus (P).

The coating layer 140 may include a nickel (Ni)-plated layer containing phosphorus (P). In this case, in the coating layer 140, binding energy between nickel (Ni) and phosphorus (P) may be lower than binding energy between nickel (Ni) and fluorine (F). Further, the higher the content of phosphorus (P), the lower the activation energy required for adsorption of fluorine radicals (F*) may be. Therefore, as the content of phosphorus (P) in nickel (Ni) increases, the adsorption rate of fluorine radicals (F*) may increase. Accordingly, the amount or concentration of fluorine gas (F₂) etchant generated from fluorine radicals (F*) may be secured.

The content of phosphorus (P) in the coating layer 140 may be in the range of about 3% to about 16%. In this specification, the content of phosphorus (P) may mean atomic percent (at. %) unless otherwise specified. Etch selectivity during processing of the substrate 10 may be adjusted by adjusting the content of phosphorus (P) in the coating layer 140. If the content of phosphorus (P) in the coating layer 140 is lower than the aforementioned range, etch selectivity may not be sufficiently secured. If the content of phosphorus (P) in the coating layer 140 is higher than the aforementioned range, etching efficiency may be reduced.

In the substrate processing apparatus 100, when a process gas is supplied from the gas supply region R1 to the plasma generation region R2, the power supply unit 174 may apply power to the upper electrode 154 in order to generate plasma in the plasma generation region R2. The plasma generated in the plasma generation region R2 may include a plurality of components. For example, the plasma may include radicals, ions, electrons, ultraviolet light, etc.

The plasma generated in the plasma generation region R2 may be supplied to the recombination region R3. In an embodiment, only radicals among the components of the plasma may be supplied to the recombination region R3, and components such as ions and electrons may be removed, rather than being supplied to the recombination region R3. For example, components such as ions and electrons may be blocked without passing through the ion blocker 156. In regions including the recombination region R3, the radical components may react with the radicals adsorbed to the showerhead 130 and may be recombined, thereby generating etchant. The recombination of the radical components may mainly occur in the recombination region R3. However, the region in which the radicals are recombined is not limited to the recombination region R3. The generated etchant gas may be sprayed to the processing region R4 on the substrate 10, whereby an etching process or a cleaning process may be performed on the substrate 10.

The gas distribution module 150 according to the present disclosure may include a purge gas supply unit 200. The purge gas supply unit 200 may supply a purge gas to the recombination region R3, thereby adjusting the recombination rate of fluorine radicals (F*).

The purge gas supply unit 200 includes a purge gas supply source 210, which stores a purge gas, a purge gas supply line 220 connected between the purge gas supply source 210 and the recombination region R3, and a flow rate control valve 230, which controls the flow rate of the purge gas supplied through the purge gas supply line 220.

The purge gas supply source 210 may store a purge gas to be supplied to the recombination region R3. The purge gas supply source 210 may receive a purge gas through an external supply line and may store the purge gas. The purge gas supply line 220 may extend from the purge gas supply source 210 and may be connected to the recombination region R3. The purge gas supply line 220 may communicate with the purge gas supply holes PH5 in the showerhead 130. The flow rate control valve 230 may be provided on a part of the purge gas supply line 220 in order to control opening and closing of the purge gas supply line 220. The flow rate control valve 230 may control the degree of opening of the purge gas supply line 220. The flow rate control valve 230 may be controlled by an upper-level controller.

According to the embodiment of the present disclosure, fluorine radicals (F*) may be generated in the plasma generation region R2, and the fluorine radicals (F*) may flow to the recombination region R3 through the through-holes PH3 formed in the ion blocker 156 and may be combined with one another in the recombination region R3, thereby generating fluorine gas (F₂).

According to the embodiment of the present disclosure, the purge gas supply unit 200 may supply a purge gas containing at least one of argon (Ar), nitrogen (N₂), helium (He), or hydrogen (H₂) to the recombination region R3, thereby adjusting the recombination rate of fluorine radicals (F*).

According to the embodiment of the present disclosure, there may be provided a pressure gauge 250 configured to measure the pressure of the fluorine gas (F₂) in the recombination region R3. The pressure gauge 250 may measure the pressure of the gas in the recombination region R3 through a tube provided through the support ring 162. The pressure gauge 250 may measure the pressure of the fluorine gas (F₂) and may transmit the measured pressure value information to a controller (not shown). The controller may control the flow rate control valve 230 based on the received pressure value information. That is, the purge gas supply unit 200 may control the flow rate of the purge gas according to the pressure of the fluorine gas (F₂) measured by the pressure gauge 250. The pressure gauge 250 measures the internal pressure in the recombination region R3. When the recombination rate of the fluorine radical (F*) is high, a high pressure is measured, and when the pressure of the fluorine radical (F*) is low, a low pressure is measured. To ensure that the recombination rate of the fluorine radicals (F*) meets the standard, if the pressure in the recombination region R3 is low, the purge gas supply unit 200 may supply a purge gas to the recombination region R3 at a high flow rate.

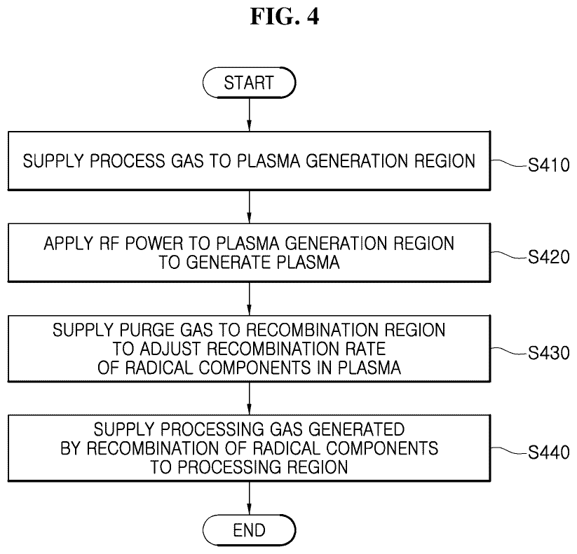

FIG. 4 is a flowchart showing a method of processing the substrate by the gas distribution module 150 according to the present disclosure. The substrate processing method according to the present disclosure includes a step of supplying a process gas to the plasma generation region R2 (S410), a step of applying RF power to the plasma generation region R2 to generate plasma (S420), a step of supplying a purge gas to the recombination region R3 to adjust the recombination rate of radical components in the plasma (S430), and a step of supplying a processing gas generated by recombination of the radical components in the recombination region R3 to the processing region R4 on the substrate 10 (S440).

In step S410, the gas supply unit 172 supplies a process gas to the plasma generation region R2 through the through-holes PH1 in the gas distribution plate 152. The process gas may include at least one of fluorine (F), nitrogen (N₂), argon (Ar), or helium (He).

In step S420, the power supply unit 174 applies RF power to the upper electrode 154, thereby generating plasma in the plasma generation region R2. The ion blocker 156 located in the lower side of the plasma generation region R2 is grounded. Plasma may be generated by applying RF power to the process gas present in the plasma generation region R2. Radical components among the components of the generated plasma may flow from the plasma generation region R2 to the recombination region R3 through the ion blocker 156.

In step S430, the purge gas supply unit 200 may supply a purge gas to the recombination region R3, thereby adjusting the recombination rate of the radical components in the plasma. Fluorine radicals (F*) may be generated in the plasma generation region R2, and the fluorine radicals (F*) may flow to the recombination region R3 through the ion blocker 156 and may be combined with one another in the recombination region R3, thereby generating fluorine gas (F₂), which corresponds to a processing gas.

The step of adjusting the recombination rate of the radical components (S430) includes a step of measuring the pressure of the gas in the recombination region R3 and a step of controlling the flow rate of the purge gas according to the pressure of the gas. In the present disclosure, the pressure due to the gas in the recombination region R3 is measured by the pressure gauge 250. The pressure gauge 250 may provide internal pressure information of the recombination region R3 to the controller (not shown), and the controller may control the flow rate of the purge gas supplied to the recombination region R3 according to the measured pressure. The purge gas may include at least one of argon (Ar), nitrogen (N₂), helium (He), or hydrogen (H₂).

In step S440, the fluorine gas (F₂) generated in the recombination region R3 is supplied to the processing region R4 on the substrate 10 through the showerhead 130. A specific material, i.e., a silicon germanium (SiGe) layer, on the substrate 10 may be etched by the fluorine gas (F₂). In the present disclosure, since the purge gas is supplied to the recombination region R3 to adjust the recombination rate of the fluorine radicals (F*), the etch rate for silicon germanium (SiGe) on the substrate 10 may be further improved.

As is apparent from the above description, according to the present disclosure, since the purge gas supply unit supplies a purge gas to the recombination region, it may be possible to adjust the recombination rate of radical components in the recombination region, thereby preventing damage to the substrate and increasing an etch rate.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. A gas distribution module configured to supply a gas to a processing region in a substrate processing apparatus using plasma, the gas distribution module comprising:
an upper electrode;
an ion blocker disposed under the upper electrode to form a plasma generation region;
a showerhead disposed under the ion blocker to form a recombination region; and
a purge gas supply unit configured to supply a purge gas to the recombination region.

2. The gas distribution module as claimed in claim 1, wherein the purge gas supply unit comprises:
a purge gas supply source configured to store the purge gas;
a purge gas supply line connected between the purge gas supply source and the recombination region; and
a flow rate control valve configured to control a flow rate of the purge gas supplied through the purge gas supply line.

3. The gas distribution module as claimed in claim 2, wherein the showerhead comprises a purge gas supply hole formed in an upper surface thereof so as to allow the purge gas to flow to the recombination region therethrough, and
wherein the purge gas supply line communicates with the purge gas supply hole.

4. The gas distribution module as claimed in claim 1, wherein fluorine radicals are generated in the plasma generation region, and
wherein the fluorine radicals flow to the recombination region through a through-hole formed in the upper electrode and are combined with one another in the recombination region to generate fluorine gas.

5. The gas distribution module as claimed in claim 4, wherein the purge gas supply unit supplies a purge gas containing at least one of argon (Ar), nitrogen (N₂), helium (He), or hydrogen (H₂) to the recombination region to adjust a recombination rate of the fluorine radicals.

6. The gas distribution module as claimed in claim 4, further comprising a pressure gauge configured to measure a pressure in the recombination region,
wherein the purge gas supply unit controls a flow rate of the purge gas according to the pressure measured by the pressure gauge.

7. The gas distribution module as claimed in claim 1, further comprising a gas distribution plate disposed on the upper electrode,
wherein a gas supply region is formed in a space between the gas distribution plate and the upper electrode, and
wherein the gas distribution plate comprises a first through-hole formed therein so as to communicate with a gas supply unit configured to supply a process gas for generation of plasma.

8. The gas distribution module as claimed in claim 1, wherein the upper electrode is electrically connected to a power supply unit configured to supply radio-frequency (RF) power for generation of plasma, and comprises a second through-hole formed therein so as to allow a process gas to flow from the gas supply region to the plasma generation region therethrough.

9. The gas distribution module as claimed in claim 1, wherein the ion blocker comprises a third through-hole formed therein so as to allow radical components of plasma generated in the plasma generation region to pass therethrough.

10. The gas distribution module as claimed in claim 1, wherein the showerhead comprises a fourth through-hole formed therein so as to allow fluorine gas generated by recombination of fluorine radicals in the recombination region to pass therethrough.

11. A substrate processing method performed by a gas distribution module configured to supply a processing gas to a processing region on a substrate in a substrate processing apparatus using plasma, wherein the gas distribution module comprises:
a gas distribution plate;
an upper electrode disposed under the gas distribution plate to form a gas supply region;
an ion blocker disposed under the upper electrode to form a plasma generation region;
a showerhead disposed under the ion blocker to form a recombination region; and
a purge gas supply unit configured to supply a purge gas to the recombination region, and
wherein the substrate processing method comprises:
supplying a process gas to the plasma generation region;
applying RF power to the plasma generation region to generate plasma;
supplying the purge gas to the recombination region to adjust a recombination rate of radical components in the plasma; and
supplying the processing gas generated by recombination of the radical components in the recombination region to the processing region.

12. The substrate processing method as claimed in claim 11, wherein fluorine radicals are generated in the plasma generation region, and
wherein the fluorine radicals flow to the recombination region through the ion blocker and are combined with one another in the recombination region to generate fluorine gas.

13. The substrate processing method as claimed in claim 12, wherein adjusting the recombination rate of the radical components comprises:
measuring a pressure of a gas in the recombination region; and
controlling a flow rate of the purge gas according to the pressure.

14. The substrate processing method as claimed in claim 11, wherein the process gas comprises at least one of fluorine (F), nitrogen (N₂), argon (Ar), or helium (He).

15. The substrate processing method as claimed in claim 11, wherein the purge gas comprises at least one of argon (Ar), nitrogen (N₂), helium (He), or hydrogen (H₂).

16. A substrate processing apparatus using plasma, the substrate processing apparatus comprising:
a process chamber configured to form a processing region on a substrate;
a substrate support unit disposed in the process chamber to support the substrate;
a gas supply unit configured to supply a process gas for generation of plasma;
a power supply unit configured to supply radio-frequency (RF) power for generation of plasma; and
a gas distribution module configured to receive the process gas supplied from the gas supply unit, to generate the plasma using the RF power supplied from the power supply unit, and to distribute a processing gas from the plasma to the processing region,
wherein the gas distribution module comprises:
a gas distribution plate comprising a first through-hole formed therein so as to communicate with the gas supply unit;
an upper electrode disposed under the gas distribution plate to form a gas supply region, the upper electrode being electrically connected to the power supply unit, the upper electrode comprising a second through-hole formed therein so as to allow a process gas to flow from the gas supply region therethrough;
an ion blocker disposed under the upper electrode to form a plasma generation region, the ion blocker comprising a third through-hole formed therein so as to allow radical components of plasma generated in the plasma generation region to pass therethrough;
a showerhead disposed under the ion blocker to form a recombination region, the showerhead comprising a fourth through-hole formed therein so as to allow fluorine gas generated by recombination of fluorine radicals in the recombination region to pass therethrough;
a support ring located on an upper side of a peripheral portion of the showerhead to support a lower side of a peripheral portion of the ion blocker; and
a purge gas supply unit configured to supply a purge gas to the recombination region.

17. The substrate processing apparatus as claimed in claim 16, wherein the purge gas supply unit comprises:
a purge gas supply source configured to store the purge gas;
a purge gas supply line connected between the purge gas supply source and the recombination region; and
a flow rate control valve configured to control a flow rate of the purge gas supplied through the purge gas supply line.

18. The substrate processing apparatus as claimed in claim 16, wherein fluorine radicals are generated in the plasma generation region, and
wherein the fluorine radicals flow to the recombination region through a through-hole formed in the ion blocker and are combined with one another in the recombination region to generate fluorine gas.

19. The substrate processing apparatus as claimed in claim 18, wherein the purge gas supply unit supplies a purge gas containing at least one of argon (Ar), nitrogen (N₂), helium (He), or hydrogen (H₂) to the recombination region to adjust a recombination rate of the fluorine radicals.

20. The substrate processing apparatus as claimed in claim 18, wherein the gas distribution module further comprises a pressure gauge configured to measure a pressure of the fluorine gas in the recombination region, and
wherein the purge gas supply unit controls a flow rate of the purge gas according to the pressure of the fluorine gas measured by the pressure gauge.
